(19) United States
(12) Patent Application Publication
(10) Pub. No.: US 2025/0199422 A1
(43) Pub. Date: Jun. 19, 2025

(54) INDIVIDUAL MIRROR OF A PUPIL FACET MIRROR AND PUPIL FACET MIRROR FOR AN ILLUMINATION OPTICAL UNIT OF A PROJECTION EXPOSURE APPARATUS

(71) Applicant: Carl Zeiss SMT GmbH, Oberkochen (DE)

(72) Inventors: Stefan LIPPOLDT, Aalen (DE); Markus HAUF, Ulm (DE); Martin ENDRES, Koenigsbronn (DE)

(21) Appl. No.: 19/063,773

(22) Filed: Feb. 26, 2025

Related U.S. Application Data
(63) Continuation of application No. PCT/EP2023/073664, filed on Aug. 29, 2023.

(30) Foreign Application Priority Data
Sep. 5, 2022 (DE) 10 2022 209 214.7

(51) Int. Cl. G03F 7/00; G01D 5/14; G02B 26/08; G02B 26/12

(52) U.S. Cl. CPC G03F 7/70825; G01D 5/14; G02B 26/0816; G02B 26/12; G03F 7/70116; G03F 7/70141; G03F 7/70516; G03F 7/70816; G03F 7/7085

(57) ABSTRACT

An individual mirror of a pupil facet mirror of an illumination optical unit of a projection exposure apparatus is mounted so as to be pivotable about two pivot axes. A ratio of the pivotability of the individual mirror about the two pivot axes is at least 2:1.

### CROSS-REFERENCE TO RELATED APPLICATIONS

The present application is a continuation of, and claims benefit under 35 USC 120 to, international application No. PCT/EP2023/073664, filed Aug. 29, 2023, which claims benefit under 35 USC 119 of German Application No. 10 2022 209 214.7, filed Sep. 5, 2022. The entire disclosure of each of these applications is incorporated by reference herein.

### FIELD

The disclosure relates to an individual mirror of a pupil facet mirror and to a pupil facet mirror for an illumination optical unit of a projection exposure apparatus. The disclosure further relates to an illumination optical unit, an illumination system, an optical system and a projection exposure apparatus having such a pupil facet mirror. The disclosure further relates to a method for producing a microstructured or nanostructured device and to a device produced in accordance with the method. In addition, the disclosure relates to a method for calibrating the pivoting of an individual mirror.

### BACKGROUND

Illumination optical units for projection exposure apparatuses are known, for example, from DE 10 2018 214 223 A1, U.S. Pat. Nos. 6,658,084 B2 and 9,063,336 B2.

For various reasons, it may be desirable to make the individual mirrors of a pupil facet mirror, which are also referred to as pupil facets, displaceable, for example pivotable. However, the practical implementation of switchable pupil facets can be a technically very challenging task. There is therefore an ongoing desire to improve pupil facets, for example with regard to their switchability.

### SUMMARY

The present disclosure seeks to provide improved pupil facets, for example with regard to their switchability.

The disclosure includes making individual mirrors of a pupil facet mirror pivotable, wherein a ratio of the pivotability about two transversely, such as perpendicularly, extending pivot axes is at least 2:1, such as at least 3:1, for example at least 5:1, for example at least 10:1, for example at least 20:1, for example at least 30:1, for example at least 50:1. The ratio of the pivotability of the individual mirror about the two pivot axes may correspond for example to approximately the aspect ratio of the object field of the projection exposure apparatus and/or the aspect ratio of individual field facets.

The pivotability of the individual mirror can be anisotropic. It may be greater in a first direction than in a second direction, which differs from, for example is perpendicular to, the former.

By reducing the pivotability of the individual mirror with respect to at least one of the two pivot axes, the effort used for stable and precise positioning of the individual mirror can be reduced. In addition, different aspects of the bearing of the individual mirror can be improved.

Without limiting the generality, the individual mirror may have a reflection surface that is polygonal, such as quadrilateral, for example rectangular, non-square or square, hexagonal or round, such as a circular.

The reflection surface may have a rotational symmetry of order 2 and/or 3.

The order of the rotational symmetry of the reflection surface may be different from the order of a rotational symmetry of the pivotability of the individual mirror. For example, it can be different from the order of a rotational symmetry of the arrangement of the pivot axes of the individual mirror.

The individual mirror may have the same dimensions but different pivotability regions for example in the direction perpendicular to the pivot axes. It has been shown that this can improve, for example simplify, the positioning of the individual mirror.

The use of the individual mirror for a pupil facet mirror should not be understood restrictively. Corresponding individual mirrors can also be used in a field facet mirror or another facet mirror. They can generally be used in a multi-mirror module, such as a MEMS module. The following description applies accordingly to such uses.

Without limiting the generality, the diameter of the reflection surface, such as the incircle diameter, can be in the range of 1 millimeters (mm) to 20 mm. For example, the diameter may be 10 mm at most. I For example, the diameter may be at least 2 mm, such as at least 3 mm. For example, the diameter can be about 6 mm.

According to one aspect, the larger of the two pivotability regions is at most +/−50 mrad, such as at most +/−30 mrad, for example at most +/−15 mrad, for example at most +/−5 mrad, for example at most +/−3 mrad. For example, it may also have at least corresponding values.

According to one aspect, the smaller of the two pivotability regions is at most +/−25 mrad, such as at most +/−15 mrad, for example at most +/−10 mrad, for example at most +/−5 mrad, for example at most +/−5 mrad, for example at most +/−3 mrad, for example at most +/−2 mrad, for example at most +/−1 mrad, for example at most +/−0.5 mrad, for example at most +/−0.2 mrad and for example at most +/−0.1 mrad.

Thus, it can be approximately one order of magnitude smaller than the pivotability region which is known for active pupil facets.

It could be shown that the features resulting from the displaceability of the pupil facets, such as the increase in the mean illuminator efficiency, can also be achieved in large parts with a reduced pivotability region.

In general, in a conventional fly's eye condenser with static pupil facets, each pupil facet is assigned exactly to one field facet as part of the channel assignment. The surface (normal and radius of curvature) of the pupil facet is therefore usually selected and configured such that it images the field facet assigned to it into the object field. A plurality of pupil facets can form a group, wherein the pupil facets of one group are assigned to the same field facet (cf. U.S. Pat. No. 6,658,084 B2). Since the pupil facets are static, this assignment can no longer be changed after production and assembly.

The field facets can be active, i.e. displaceable, in this case. They can be switched from one pupil facet to another. At a fixed time, however, a field facet irradiates only a single pupil facet. Therefore, only pupil facets from different groups can emit light at the same time, i.e. contribute to the illumination of the object field. Pupil facets from the same group cannot emit light at the same time. Thus, the desired illumination settings (in short, settings) are already known during the design of the illuminator (the illumination optical unit). The grouping of the pupil facets can then be optimized for these settings, and as a result the highest possible illuminator efficiency can be achieved for these settings. Other settings can then generally no longer be operated with full illuminator efficiency.

The illuminator efficiency of a setting is calculated from the ratio of the number of light-emitting pupil facets to the number of existing field facets. If each pupil facet group is queried at least once in a setting, this corresponds to an illuminator efficiency of 100%. If specific groups are not queried in a setting, the illuminator efficiency decreases accordingly.

In addition, there are two types of pupil filling degrees that are used to characterize an illumination optical unit.

The setting pupil filling degree is given by the ratio of the number of pupil facets queried by a setting to the total number of pupil facets available.

The system pupil filling degree indicates the ratio of total existing field facets to total existing pupil facets.

The illuminator efficiency is generally a function of the setting pupil filling degree of an illumination system. When using static pupil facets, a mean illuminator efficiency of about 67% can be achieved with a system pupil filling degree of 20% and a setting pupil filling degree of 20%. This is due to the fact that at a 20% setting, in a typical case, many pupil facet groups are queried a plurality of times, while other groups are not queried at all. This mutual blocking of the pupil facets is also called a setting conflict. Such setting conflicts can be reduced, for example completely avoided, via a switchable, i.e. pivotable, embodiment of the pupil facets. In the case of switchable pupil facets, an individual pupil facet may at any fixed time lead only the light of an individual field facet to the reticle, but it can be pivoted in such a way that it guides illumination radiation from a specific field facet to the reticle at one time and guides illumination radiation from another field facet to the reticle at another time. A setting conflict can be resolved for example by switching a queried pupil facet which is switched to an already used field facet to an unused field facet. Provided the switchable pupil facets can cover the entire field facet module, all conceivable settings can also be supported.

Surprisingly, it could be shown that the mean illuminator efficiency can be significantly increased if the pupil facets do not cover the entire field facet module, but can control only a few, such as two, three, four or five, field facets.

For example, it could be shown that the features resulting from the switchability of the pupil facets can also be achieved to a large extent with a reduced switching range (displaceability region). In this way, the design effort may be reduced. In addition, different aspects of the bearing, such as the thermal conductivity thereof, can be improved.

It was furthermore found that the effort used for a stable and precise displacement of the pupil facets can be further reduced if the field facets and/or the object field usually have a strongly elongated shape, such as an aspect ratio of at least 5:1, for example at least 10:1, for example 13:1.

According to a further aspect, the smaller of the two pivotability regions may be at most +/−2 mrad, such as at most +/−1 mrad, for example at most +/−0.5 mrad.

In this case, the larger of the two pivotability regions can characterize the pivotability about an axis perpendicular to the scanning direction within the plane of the pupil facet module.

The smaller of the two pivotability regions can indicate the pivotability about a second axis perpendicular to the first axis, i.e. parallel to the scanning direction, within the plane of the pupil facet module.

A reference to the scanning direction is to be understood here to mean in each case that the individual mirror in an illumination optical unit is arranged such that its pivoting about an axis oriented perpendicular to the scanning direction leads to a displacement of the illumination radiation in the object field parallel to the scanning direction, or that its pivoting about an axis oriented parallel to the scanning direction leads to a displacement of the illumination radiation in the object field perpendicular to the scanning direction.

Since the desired switching range of the pupil facets in the scanning direction is only very small, the switching range is almost one-dimensional. It has been found that this can be used to simplify the bearing of the pupil facets and/or the actuation used for their displaceability and/or the sensor device for detecting their displacement position, for example without this leading to a significant loss of quality.

Different aspects that result from this and can lead to benefits individually or in combination are described below.

According to one aspect, the bearing of the pupil facets can include a flexure, such as a universal joint.

According to an aspect, the bearing of the individual mirror for each pivoting degree of freedom includes one or more leaf springs, wherein the leaf springs for one pivoting degree of freedom are thicker and/or stiffer than the leaf springs for the other pivoting degree of freedom.

It was found that a reduction of the pivotability region by a factor x at a given actuator force allows a corresponding increase in the stiffness of the leaf springs, or generally of the universal joint, in this direction.

As a result, the natural frequency of the tilt modes increases by a factor √x. This can enhance the robustness of the pivot in this direction against mechanical vibrations.

In addition, the possibility of using thicker leaf springs leads to a lower thermal resistance from the mirror to the mirror carrier, such as by a factor x^{-1/3}. This can be advantageous for the dissipation of the heat power introduced by the illumination radiation, such as by the EUV radiation, to the individual mirror.

The natural frequencies of the individual mirrors can be at least 300 Hz, such as at least 500 Hz, for example in one direction. In a direction perpendicular thereto, the natural frequencies of the tilt modes of the individual mirrors may be at least 1000 Hz, such as at least 1500 Hz.

According to an aspect, the bearing of the individual mirror for one or both of the pivoting degrees of freedom has end stops for delimiting the pivotability region.

This can improve the accuracy of the pivotability. The end stops can be used to define precise pivot positions.

Such end stops can also be used to calibrate the displacement position.

According to an aspect, at most one, for example exactly one, of the pivoting movements about the two pivot axes is detected via a sensor device. In other words, the individual mirror may have only a single sensor device for detecting the pivoting of the individual mirror about only one of the two pivot axes. The pivoting about the other of the two pivot axes can be performed without a sensor. For example, the number of the pivoting degrees of freedom detected by way of sensor may be smaller than the number of the pivoting degrees of freedom that are controllable by way of actuator.

In this case, the pivoting movement about the pivot axis with the larger pivotability region can be detected by way of sensor.

For example, it is possible to control at most one, for example exactly one, of the two pivoting movements with closed-loop control. The other pivoting movement, such as the pivoting movement about the axis with the smaller pivotability region, can be controlled for example without feedback. For this pivoting movement for example, i.e. for the pivoting movement about the axis with the smaller pivotability region, end stops for delimiting the pivotability region may be provided.

In general, it is even possible to control both pivoting movements merely with open-loop control, i.e. without feedback.

This can considerably simplify the design effort and the positioning of the individual mirrors.

According to an aspect, a sensor device with one or more eddy current sensors can be used for detecting the pivot position of the individual mirror.

This can help enable a particularly simple, robust sensor concept.

According to an aspect, the pivot axes and the flexures can lie in the same plane. For example, the leaf springs with which the pivot axes are realized can also lie in this plane.

This can help allow for a particularly flat design. The flat design can considerably simplify the manufacture of the flexure, for example in comparison with flexure elements whose effective rotational axes lie in the mirror surface and whose leaf springs are consequently arranged so as to extend out of the plane.

According to an aspect, the pivot axes can be spaced apart from the reflection surface. The pivot axes can be arranged for example behind or under the reflection surface of the pupil facets.

The fact that the tilt axes are below the mirror surface means that the mirror surface moves sideways during tilting. However, it has been shown that this is not an issue in the case of the small tilt angles mentioned above.

The pivot axes may be spaced apart from the reflection surface, for example in the direction of a mirror normal, by at least 1 mm, such as at least 2 mm, for example at least 3 mm.

The distance of the pivot axes from the reflection surface in the direction of the surface normal thereof may be at least one fifth of, for example at least one third of, for example at least half, a mirror diameter.

According to an aspect, a reference position sensor may be provided for ascertaining one or more reference signals for a pivot position for one or both of the pivot axes.

For incremental sensors such as encoders, this is often integrated as a reference index sensor. The reference index sensor always points into the same increment, which is why the absolute positions can also be reproduced very precisely with incremental encoders.

A reference position sensor does not need to be accurate over the entire measurement range but reproduce only the reference position reproducibly, which can be desirable if this is easier to implement under the given boundary conditions.

The disclosure moreover relates to a pupil facet mirror for an illumination optical unit of a projection exposure apparatus having a plurality of individual mirrors according to the preceding description.

The distance between adjacent individual mirrors may be at most 1 mm, such as at most 500 μm, for example at most 400 μm, for example at most 300 μm. The distance here for example refers to the width of the gap between adjacent individual mirrors, such as the minimum width of the gap between adjacent individual mirrors.

The disclosure also relates to an illumination optical unit for a projection exposure apparatus with a field facet mirror having a plurality of field facets and a pupil facet mirror according to the preceding description, by which the field facets can be imaged into an object field.

The features of the illumination optical unit according to the disclosure result from what was described above.

According to an aspect, at least a subset of the pupil facets is displaceable such that the corresponding pupil facets can be assigned to exactly or at least two, three, four or five different field facets in each case.

This means that they can be positioned in such a way that they image the respective facet into the object field.

The subset may comprise at least 50%, such as at least 70%, for example at least 90%, for example all of the pupil facets of the pupil facet mirror.

In general, it is possible to form different pupil facets with different pivotability regions. This can further increase the illuminator efficiency. At the same time, features that can result from a lower displaceability of the pupil facets can be at least partially achieved.

The individual mirrors of the pupil facet mirror can be arranged in for example such that they have a larger pivotability region in the scanning direction than in the cross-scanning direction.

One of the two pivot axes, for example the pivot axis with the larger displacement region, may be aligned for example perpendicular to the scanning direction.

One of the two pivot axes, such as the pivot axis with the smaller displacement region, may be aligned for example perpendicular to the cross-scanning direction.

The disclosure also relates to an illumination system which, in addition to the illumination optical unit described above, has a radiation source for generating illumination radiation, such as an EUV radiation source.

An optical system for a projection exposure apparatus has, in addition to the illumination optical unit described above, a projection optical unit for imaging a reticle arranged in the object field into an image field.

A projection exposure apparatus according to the disclosure has an illumination optical unit according to the preceding description, a radiation source for generating illumination radiation, such as in the EUV range, and a projection optical unit for imaging a reticle arranged in the object field into an image field.

The disclosure also relates to an arrangement of an individual mirror according to the preceding description in an illumination optical unit for a projection exposure apparatus in such a way that the pivot axis with the larger displacement region is aligned perpendicular to the scanning direction and the pivot axis with the smaller displacement region is aligned perpendicular to the cross-scanning direction.

The disclosure also relates to a method for producing a microstructured or nanostructured device and to a device produced in accordance with the method. For this purpose, a projection exposure apparatus according to the preceding description is provided and structures are imaged on a reticle arranged in the object field on a radiation-sensitive coating of a wafer arranged in the image field.

The disclosure also relates to a method for calibrating the pivoting of an individual mirror according to the preceding description. For this purpose, the individual mirror is pivoted, for example at a constant pivoting speed. Here, the profile of a counter-electromotive force is ascertained. Here, a jump site in the profile of the counter-electromotive force is ascertained. A calibration support point can then be ascertained from a current value at the jump site.

In general, a current-angle characteristic can be ascertained.

According to one aspect, two calibration support points are ascertained for each pivoting degree of freedom, which can be used to ascertain offset and/or gain corrections.

A reference position sensor can also be used to ascertain a reference signal. This sensor can be arranged in a central region of the pivoting region.

Further advantages and details of the disclosure will become apparent from the description of exemplary embodiments with reference to the figures.

### BRIEF DESCRIPTION OF THE DRAWINGS

In the figures:

FIG. 1 shows schematically and with regard to an illumination optical unit the meridional section of a microlithographic projection exposure apparatus;

FIG. 2 shows a plan view on a facet arrangement of a field facet mirror of the illumination optical unit of the projection exposure apparatus according to FIG. 1;

FIG. 3 shows a plan view on a facet arrangement of a pupil facet mirror of the illumination optical unit of the projection exposure apparatus according to FIG. 1;

FIG. 4 shows an illustration similar to FIG. 2 of a facet arrangement of a further embodiment of a field facet mirror;

FIGS. 5 to 7 show exemplary illustrations of an embodiment of a pupil facet mirror with a plurality of pupil facets (individual mirror) in perspective illustration with a stepped section (FIG. 5), in plan view (FIG. 6) and in a cross section (FIG. 7); and

FIG. 8 shows an exemplary illustration of the tilting of pupil facets in order to control three adjacent field facets.

### DETAILED DESCRIPTION

A microlithographic projection exposure apparatus 1 serves for producing a microstructured or nanostructured electronic semiconductor device. A light source 2 emits EUV radiation used for illumination in the wavelength range of, for example, between 5 nm and 30 nm. The light source 2 can be a GDPP (gas discharge produced plasma) source or an LPP (laser produced plasma) source. A radiation source based on a synchrotron can also be used for the light source 2. A person skilled in the art will find information regarding such a light source in U.S. Pat. No. 6,859,515 B2, for example. EUV illumination light or illumination radiation 3 is used for illumination and imaging within the projection exposure apparatus 1. The EUV illumination light 3 downstream of the light source 2 firstly passes through a collector 4, which can be, for example, a nested collector having a multi-shell construction known from the prior art, or alternatively an ellipsoidally shaped collector. A corresponding collector is known from EP 1 225 481 A2. Downstream of the collector 4, the EUV illumination light 3 firstly passes through an intermediate focal plane 5, which can be used for separating the EUV illumination light 3 from unwanted radiation or particle portions. After passing through the intermediate focal plane 5, the EUV illumination light 3 is incident first on a field facet mirror 6. An overall beam of the illumination light 3 has a numerical aperture a in the intermediate focal plane 5.

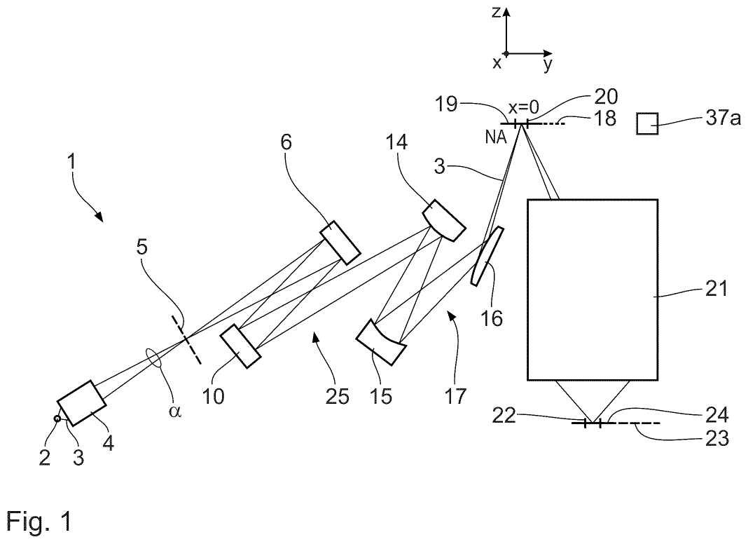

In order to facilitate the description of positional relationships, a Cartesian global xyz-coordinate system is in each case depicted in the drawing. In FIG. 1, the x-axis extends perpendicularly to the plane of the drawing and out of the latter. The y-axis extends towards the right in FIG. 1. The z-axis runs upwards in FIG. 1.

In order to facilitate the description of positional relationships for individual optical components of the projection exposure apparatus 1, a Cartesian local xyz- or xy-coordinate system is in each case also used in the following figures. The respective local xy-coordinates span, unless described otherwise, a respective principal arrangement plane of the optical component, for example a reflection plane. The x-axes of the global xyz-coordinate system and of the local xyz- or xy-coordinate systems run parallel to one another. The respective y-axes of the local xyz- or xy-coordinate systems are at an angle with respect to the y-axis of the global xyz-coordinate system which corresponds to a tilting angle of the respective optical component about the x-axis.

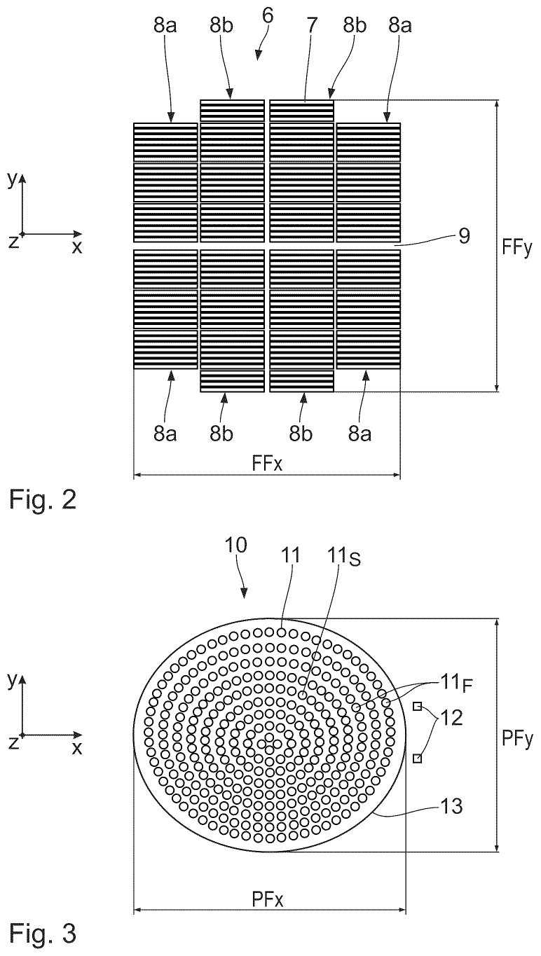

FIG. 2 shows, in an exemplary manner, a facet arrangement of field facets 7 of the field facet mirror 6. The field facets 7 are rectangular and have in each case the same x/y aspect ratio. The x/y aspect ratio can be for example 12/5, can be 25/4 or can be 104/8.

The field facets 7 define a reflection surface of the field facet mirror 6 and are grouped into four columns with six to eight field facet groups 8a, 8b each. The field facet groups 8a have seven field facets 7 each. The two additional peripheral field facet groups 8b of the two central field facet columns have four field facets 7 each. The facet arrangement of the field facet mirror 6 has, between the two central facet columns and between the third and fourth facet lines, interstices 9 in which the field facet mirror 6 is shadowed by holding spokes of the collector 4.

In a variant not illustrated here, the field facet mirror 6 is constructed as a MEMS mirror array with a multiplicity of tiltable individual mirrors, with each of the field facets 7 being formed by a plurality of such individual mirrors. Such a construction of the field facet mirror 6 is known from US 2011/0001947 A1.

Both a radius of curvature of a field-facet individual-mirror group of the MEMS mirror array and also a radius of curvature of a pupil-facet individual-mirror group of the MEMS mirror array can be adapted by displacing the individual mirrors perpendicular to a mirror array arrangement plane and correspondingly tilting the individual mirrors, as is likewise described in US 2011/0001947 A1. A radius of curvature can also be adapted by tilting the individual mirrors without a corresponding displacement perpendicular to a mirror array arrangement plane, then effectively resulting in a Fresnel mirror, for example.

After reflection at the field facet mirror 6, the EUV illumination light 3 split into pencils of rays or partial beams assigned to the individual field facets 7 is incident on a pupil facet mirror 10.

The field facets 7 of the field facet mirror 6 are tiltable between a plurality of illumination tilt positions, as a result of which the direction of a beam path of the illumination light 3 reflected by the respective field facet 7 is altered and hence the point of incidence of the reflected illumination light 3 on the pupil facet mirror 10 can be altered. Corresponding field facets that are displaceable between various illumination tilt positions are known from U.S. Pat. Nos. 6,658,084 B2 and 7,196,841 B2. This facilitates the specification of an illumination setting, i.e. A distribution of illumination angles for illuminating the object field. Examples of illumination settings are known, inter alia, from DE 10 2008 021 833 A1.

FIG. 3 shows an exemplary facet arrangement of round pupil facets 11 of the pupil facet mirror 10. The pupil facets 11 are arranged around a centre in facet rings lying one inside of another. Other shapes and/or arrangements of the pupil facets 11 are possible. At least one pupil facet 11 is assigned to each partial beam of the EUV illumination light 3 reflected by one of the field facets 7, in such a way that a respective impinged facet pair comprising one of the field facets 7 and one of the pupil facets 11 predefines an object field illumination channel for the associated partial beam of the EUV illumination light 3. The channel-by-channel assignment of the pupil facets 11 to the field facets 7 is implemented on the basis of a desired illumination by the projection exposure apparatus 1.

At least a subset of the pupil facets 11 is switchable between at least two illumination tilt positions via associated actuators 12. The actuators 12 are merely schematically indicated in FIG. 3. The pupil facets 11 can be switchable between two tilt positions, between three tilt positions, between four tilt positions or even between an even greater number of tilt positions. The pupil facet mirror 10 may have different types of pupil facets 11, which are switchable in different numbers of illumination tilt positions.

The pupil facet mirror 10 may also have fixed pupil facets 11, which are designed to be fixed relative to a pupil facet carrier 13 of the pupil facet mirror 10, i.e. not switchable between tilt positions.

Via the respective illumination tilt positions of the respective field facet 7, a set of pupil facets 11 of the pupil facet mirror 10 is assigned to this field facet 7. Each of the pupil facets 11 of one of these sets is impinged upon by the illumination light 3 via exactly one of the different tilt positions of the associated field facets 7, with the result that, depending on the tilt position of the field facet 7, a specific illumination channel between this field facet 7 and one of the pupil facets 11 of the pupil facet set is formed. The illumination channels which can be used depending on the tilt position of exactly one of the field facets 7, which is to say via which the pupil facets 11 of the set of pupil facets 11 assigned to this field facet 7 can be impinged upon by the illumination light partial beam, form an illumination channel group. A field facet 7 may have more tilt positions which can be set via an actuator connected thereto than tilt positions which lead to the formation of a illumination channel. Only a tilt position which leads to the formation of an illumination channel should be referred to as a tilt position hereinafter.

Between a pupil facet 11 that may be present in the respective illumination channel and the subsequent illumination beam path of the illumination light partial beam guided via this illumination channel, the direction of this beam path can be influenced via the respective illumination tilt position of the pupil facet 11. It is possible, for example, in this way to assign one and the same pupil facet 11 to different field facets 7 via one illumination channel in each case so that a pupil facet 11 can be assigned to different field facets 7 depending on its tilt position. A fixed pupil facet 11_{F}, on the other hand, is assigned to a maximum of one field facet 7, typically to exactly one field facet.

The field facet mirror 6 has several hundred of the field facets 7, for example, 300 field facets 7. The number of pupil facets 11 of the pupil facet mirror 10 can at least equal the sum of the tilt positions of all field facets 7 of the field facet mirror 6. In this case, some of the pupil facets 11 are not used for the used assignment of pupil facets to field facets. It may be desirable if the sum of the tilt positions of all field facets 7 of the field facet mirror 6 is equal to the number of pupil facets 11.

However, a number of pupil facets 11 that is guided by the sum of the tilt positions of all field facets 7 is not mandatory. Due to the existing switchability of the pupil facets 11, it is possible to equip the pupil facet mirror 10 with a number of pupil facets 11 which is smaller than the sum of the tilt positions of all field facets 7. For example, if each of the field facets 7 has two different tilt positions, the number of pupil facets 11 can also be as large as the number of field facets 7, can be greater by 10%, can be greater by 20%, can be greater by 30%, can be greater by 40% or greater by 50%. In this case, the number of pupil facets 11 may be less than 200% of the number of field facets 7, may be less than 190%, may be less than 180% and may also be less than 170%.

In a variant which is not shown, the pupil facet mirror 10 is constructed as a MEMS mirror array with a multiplicity of tiltable individual mirrors, such as micro-mirrors, wherein each of the pupil facets 11 is formed by a plurality of such individual mirrors. Such a construction of the pupil facet mirror 10 is known from US 2011/0001947 A1.

Via the pupil facet mirror 10 (see FIG. 1) and optionally a subsequent transfer optical unit 17 consisting of three EUV mirrors 14, 15, 16, the field facets 7 are imaged into an object plane 18 of the projection exposure apparatus 1. The EUV mirror 16 is embodied as a mirror for grazing incidence (grazing incidence mirror). Arranged in the object plane 18 is an object in the form of a reticle 19, of which, with the EUV illumination light 3, an illumination region in the form of an illumination field is illuminated, which coincides with an object field 20 of a downstream projection optical unit 21 of the projection exposure apparatus 1. The object field illumination channels are superimposed in the object field 20. The EUV illumination light 3 is reflected by the reticle 19.

An overall beam of the illumination light 3 at the object field 20 has an object-side numerical aperture NA, which may lie in the range between 0.04 and 0.15, for example.

The projection optical unit 21 images the object field 20 in the object plane 18 into an image field 22 in an image plane 23. Arranged in the image plane 23 is a wafer 24 carrying a light-sensitive layer, which is exposed during the projection exposure via the projection exposure apparatus 1. During the projection exposure, both the reticle 19 and the wafer 24 are scanned in a synchronized manner in the y-direction. The projection exposure apparatus 1 is embodied as a scanner. Below, the scanning direction y is also referred to as object displacement direction.

The projection optical unit 21 has an imaging scale β. If the projection optical unit 21 images, for example, the object field 20 onto the image field 22 reduced by a factor of 4, this imaging scale β is ¼. Imaging scales of the projection optical unit 21 can lie in the range between ½ and 1/16, for example can be ⅕, ⅙, 1/7 or ⅛.

The projection optical unit 21 can be designed anamorphically with different imaging scales βx, βy in the mutually perpendicular planes xz, yz according to FIG. 1. Examples of such anamorphic projection optical units are known from U.S. Pat. Nos. 9,366,968 and 9,983,484.

βx can lie in the range from ⅓ to ⅕, and for example in the region of ¼; βy can lie in the range from ¼ to 1/10, for example in the region of ⅛.

The field facet mirror 6, the pupil facet mirror 10 and optionally the mirrors 14 to 16 of the transfer optical unit 17 are constituent parts of an illumination optical unit 25 of the projection exposure apparatus 1. The transfer optical unit 17 can optionally also be anamorphic. In a variant of the illumination optical unit 25, which is not shown in FIG. 1, the transfer optical unit 17 may also be partially or completely omitted, so that no further EUV mirror, exactly one further EUV mirror or exactly two further EUV mirrors can be arranged between the pupil facet mirror 10 and the object field 20. The pupil facet mirror 10 may be arranged in an entrance pupil plane of the projection optical unit 21.

Together with the projection optical unit 21, the illumination optical unit 25 forms an optical system of the projection exposure apparatus 1.

The field facet mirror 6 represents a first facet mirror of the illumination optical unit 25. The field facets 7 represent first facets of the illumination optical unit 25.

The pupil facet mirror 10 represents a second facet mirror of the illumination optical unit 25. The pupil facets 11 represent second facets of the illumination optical unit 25.

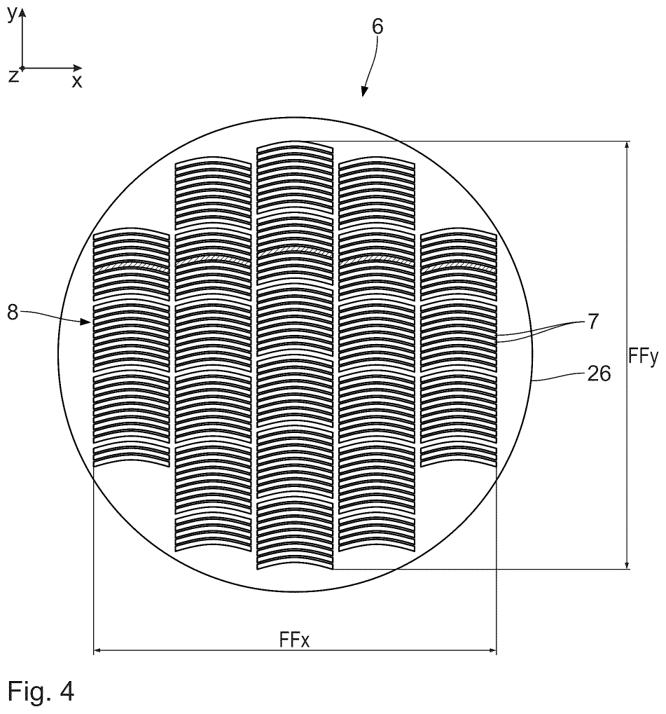

FIG. 4 shows a further embodiment of a field facet mirror 6. Components that correspond to those that were explained above with reference to the field facet mirror 6 according to FIG. 2 have the same reference signs and are only explained to the extent that they differ from the components of the field facet mirror 6 according to FIG. 2. The field facet mirror 6 according to FIG. 4 has a field facet arrangement with arcuate field facets 7. These field facets 7 are disposed in a total of five columns with, in each case, a plurality of field facet groups 8. The field facet arrangement is inscribed in a circular boundary of a carrier plate 26 of the field facet mirror 6.

The totality of the field facets 7 are accommodated on the respective carrier plate 26 of the field facet mirror 6 within an area having the dimensions FFx, FFy. These dimensions FFx, FFy are also highlighted in FIG. 2 for the field facet mirror 6 there. In FIG. 3, dimensions PFx, PFy of a surface are correspondingly highlighted, within which a totality of the pupil facets 11 are accommodated.

The field facets 7 in the embodiment according to FIG. 4 all have the same area and the same ratio of width in the x-direction to height in the y-direction, which corresponds to the x/y-aspect ratio of the field facets 7 of the embodiment according to FIG. 2.

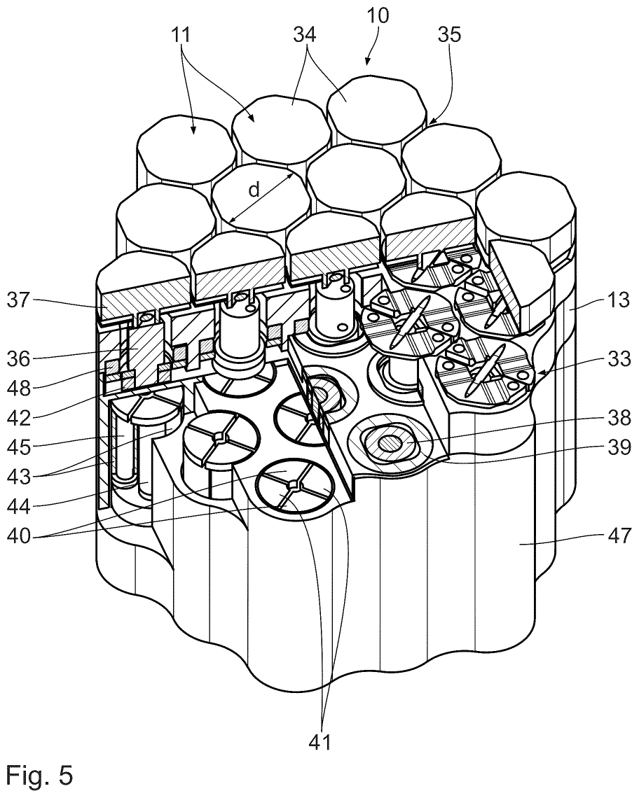

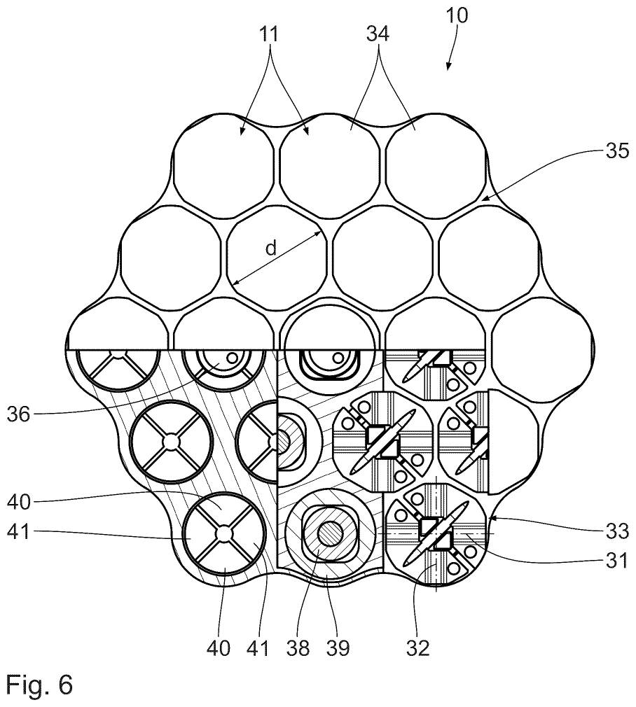

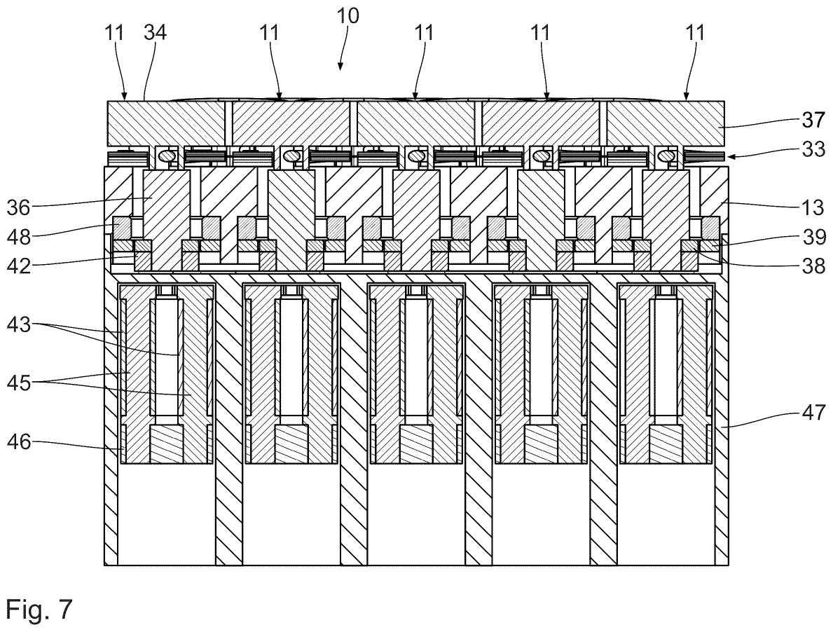

In the following, further details of the pupil facet mirror 10 are described with reference to FIGS. 5 to 7.

The pupil facet mirror 10 may have a densely packed array of pupil facets 11, as is illustrated by way of example in FIGS. 5 to 7. The pupil facets 11 are also referred to as individual mirrors in the following description of the pupil facet mirror 10.

The pupil facets 11 are actuable. They are pivotable for example about a first pivot axis 31 and a second pivot axis 32. The two pivot axes 31, 32 can be positioned perpendicular to each other for example. The pupil facets 11 are each mounted via a flexure 33. The flexure 33 is for example a universal joint.

The two pivot axes 31, 32 can be located in the plane of the flexure 33.

The pivot axes 31, 32 are implemented by leaf springs. The leaf springs with which the pivot axes 31, 32 are realized lie for example in the plane of the flexure 33. This allows for a particularly flat design. In addition, this simplifies the manufacture of the flexure 33, for example with respect to flexure elements whose effective rotational axes lie in the mirror surface.

The pivot axes 31, 32 are spaced apart from the reflection surface 34 of the individual mirrors. The pivot axes 31, 32 are located for example below or behind the reflection surface 34.

The pupil facets 11 may have different pivotability regions for example with regard to the two pivot axes 31, 32. They may have a pivotability range of at most ±15 mrad, such as ±5 mrad, for example ±3 mrad, for example in the direction perpendicular to the scanning direction (y-direction).

In the direction perpendicular thereto, that is to say for the pivoting movement in the scanning direction, the pivotability region can be about one order of magnitude smaller. The pivotability region for a pivoting movement of the individual mirrors in the scanning direction may for example be at most ±2 mrad, such as ±1 mrad, such as at most ±0.5 mrad.

The pivotability region may be determined for example roughly by the pitch of the field facets 7 or of the field facet groups 8 in the scanning direction or transversely, for example perpendicular, to the scanning direction. It can be the result for example of the ratio of the pitch to the distance between the field facet mirror 10 and the pupil facet mirror 10, for example to the distance of the field facets 7 and pupil facets 11 assigned to one another. For example, the pitch can denote here the distance between corresponding points, for example the midpoints or two peripheral points, on adjacent field facets 7 or field facet groups 8.

Different pivotability regions in the x- and y-directions can be achieved by way of an appropriate bearing of the individual mirrors. For example, the flexure may have a different design with respect to the two pivot axes 31, 32. For example, it is possible to form the leaf springs for mounting the individual mirrors differently, such as with different stiffnesses.

A stiffer spring may be thicker. A thicker design can reduce thermal resistance.

For example, it is possible to configure the bearing of the individual mirrors in such a way that the mechanical component parts for displaceability in one direction have a thermal resistance that is at most half as great as the thermal resistance of the mechanical component parts for displaceability in the other direction. This can significantly reduce the overall thermal resistance of the bearing.

The reflection surface 34 may be approximately round, for example circular, or substantially hexagonal with rounded corners. Other shapes are possible. The reflection surface may for example also be square or rectangular with an aspect ratio of at least 1.1:1, for example at least 1.2:1, for example at least 1.5:1, for example at least 2:1.

The reflection surface 34 has in each case an incircle with a diameter d of 6 mm. Other sizes are possible.

It is also possible to form different pupil facets 11 with different shapes and/or sizes of the reflection surface 34.

The individual mirrors of the pupil facet mirror 10 are spaced apart in each case. In the neutral position of the individual mirrors, a gap 35 remains between two adjacent individual mirrors. The gap 35 can have a nominal width of 400 μm.

The distance of the pivot axes 31, 32 from the reflection surface 34 in the exemplary embodiment illustrated by way of example is 3 mm.

With a pivoting movement of 5 mrad of the individual mirrors, this thus results in a lateral deflection of the mirror contour by about 15 μm.

A few details of the actuability of the pupil facets 11 are described below.

An actuator device is provided for the displacement of the individual mirrors. The actuator device comprises an actuator pin 36. The actuator pin is connected to the mirror body 37 of the individual mirrors in a power-transmitting manner.

The actuator device further comprises an annular back iron 48.

The annular back iron 48 forms a bridge made of a ferromagnetic material suitable for guiding the magnetic flux.

The actuator device also comprises end stops 38, 39 for one or both of the pivotability directions.

The end stop 38 is designed as a movable inner ring.

The end stop 39 is designed as a stationary outer ring. The inner ring may be arranged for example inside the outer ring.

The actuator device can have a pair of pole shoes 40, 41 for each of the pivoting directions.

In addition, the actuator device has a driver magnet in the form of a permanent magnet 42.

In addition, the actuator device comprises a coil pair 43, 44 for each of the pivot axes 31, 32.

A soft iron core 45 can be arranged in the interior of each coil 43, 44.

In addition, the actuator device comprises a yoke element 46. The yoke element 46 is arranged on the respective side of the coils 43, 44 opposite the mirrors and is connected to the former.

The actuator device comprises for example a pulling magnet. The yoke may comprise or consist of four soft iron cores, surrounded by the coils, and the cylindrical base plate.

The coils 43, 44 and the electronics of the actuator device are arranged in a housing 47.

The housing 47 can be for example vacuum-tight. For example, it can form a boundary between a vacuum region and a region with normal atmosphere.

The mirrors are arranged on the pupil facet carrier 13. This pupil facet carrier 13 can be for example firmly connected to the housing 47.

The two coil pairs 43, 44 are arranged relative to one another for example such that connecting lines of their central axes intersect, for example orthogonal to one another.

A magnetic flux which is in each case proportional to the controlled current can be generated with the coil pairs 43, 44 via their pole shoes 40, 41. The magnetic flux generates a Lorentz force in combination with the permanent magnet 42 attached to the actuator pin 36. This force is used to apply a torque to the individual mirror and thus to the flexure 33 via the actuator pin 36. The resulting tilt of the individual mirror is proportional to the torque and thus to the coil current. The tilt is inversely proportional to the tilt stiffness of the flexure 33.

In the exemplary embodiment illustrated by way of example in FIGS. 5 to 7, no sensors are provided. The pupil facets 11, for example the pupil facet mirror 10, are designed sensor-free. This means a considerable simplification compared with a configuration in which a sensor for capturing the deflection of the magnet 42 would have to be inserted between the actuator and the magnet 42.

As an alternative to a sensor-free configuration, a configuration in which a measurement of the tilt of the individual mirrors is envisaged only in relation to one of the two pivot axes 31, 32 may also be provided. The pivoting movement of the individual mirrors about the pivot axis with the larger pivotability region can be detected by way of sensor.

In principle, an embodiment with sensors for one of the pivot axes 31, 32 is also possible.

In a sensor-free embodiment, the mirror orientation can be set via the coil current. The coil current interacts directly with the magnetic flux and thus with the generated force and thus with the deflection of the permanent magnet 42, i.e. with the tilt of the individual mirror.

The housing 47 may for example be produced from an electrically conductive metal, for example copper or a copper compound. This means that the tilt modes of the individual mirrors are subjected to eddy current damping via the permanent magnets 42. This dampens unwanted vibrations excited by mechanical vibration.

A sensor-free embodiment of the pupil facets 11, for example of the entire pupil facet mirror 10, is for example advantageous, also with regard to the omission of otherwise used electrical feedthroughs and a purely metallic housing 47.

It has been shown that systematic reproducible thermal variations in the controlled tilt angle of the individual mirrors can be counter-compensated with the aid of a compensation model with typical correction voltages of a factor in the range of 3 to 10, at least if the thermal loads on the individual mirrors are sufficiently known.

The long-term drifts of the zero position can be addressed via an external calibration system, which detects the angular deviation of a light ray reflected by the pupil facets 11 and ascertains a correction of an actuating signal therefrom.

Alternatively, the tilt angle can also be referenced with respect to the end stops 38, 39. As shown, for example, in FIG. 5, the outer end stop ring 39 may be designed such that in both actuation directions, unique pivotability boundaries arise, i.e. pivotability boundaries that are independent of the respective other actuation direction.

For the controlled detection of the end stop positions, a current ramp can be applied to the coil pair 43 or 44 responsible for the respective pivoting direction. As a result, the permanent magnet 42 with the associated end stop ring can be deflected at a constant velocity in a quasi-stationary manner, for example below the resonance frequency. In the event of a collision of the contact surfaces of the fixed end stop ring 39 and of the moving end stop ring 38, the velocity of the permanent magnet 42 is abruptly changed. In the event of an elastic collision, the velocity of the permanent magnet 42 is reversed in direction. This can be ascertained as a jump in the counter-electromotive force. This jump can be associated with the current value at this site and thus represents a calibration support point. From the two end stop positions for each of the two pivot axes 31, 32, it is thus possible to obtain two calibration support points on the respective current-angle characteristic for the respective pivot axis 31 and 32. This is sufficient for offset and/or gain correction. This is sufficient for small pivoting angles, as shown, especially since the dominant errors are gains, for example due to a temperature increase of the magnet 42 and flexure 33, and offsets, for example due to flexure creep.

Alternatively, a reference position sensor may be provided. Using the latter, a reference signal, such as in a central region of the pivoting region, can be provided for each of the two pivot axes 31, 32 for the correction of position offset drifts. The concept is based on the finding that gain, i.e. the relationship between current change and tilt angle change, changes substantially systematically, reversibly and reproducibly. Small errors can therefore be corrected, if desired, to a sufficient extent relatively easily with models. Position offsets generally change irreversibly. However, a calibration point of the pivot axis 31 or 32 is sufficient to correct the position offsets.

According to another alternative, the pupil facets 11 can be provided with a simple sensor concept. For example, at least a subset of the pupil facets 11, for example all of the pupil facets 11, can be provided with eddy current sensors for one or both of the pivot axes 31, 32.

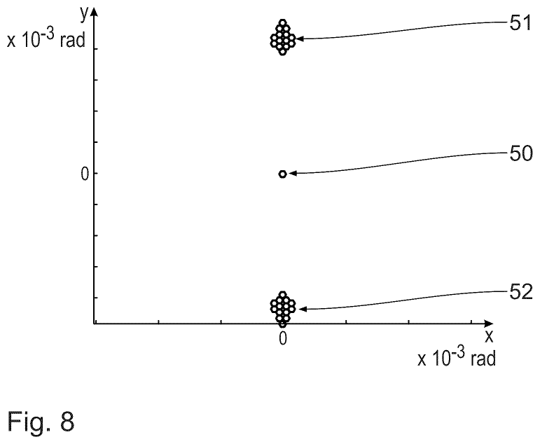

FIG. 8 shows by way of example the tilting of pupil facets 11 used to control three adjacent field facets 7. The point 50 in the middle corresponds to the neutral position of the actuator.

The upper point cloud 51 and the lower point cloud 52 correspond to the respective tilts to reach the two adjacent field facets 7. They show where the tilted surface normal is in a neutral position relative to the surface normal. As is qualitatively clear, the involved pivoting movement about the x-axis, i.e. about the axis which is perpendicular to the scanning direction, is much greater, for example by about one order of magnitude, than the involved pivoting movement about the perpendicular axis (y-axis).

For the production of a nanostructured or microstructured device, for example a semiconductor memory chip, the reticle 19 and the wafer 24 having a coating which is light-sensitive to the illumination light 3 are first provided.

Depending on a structure arrangement on the reticle 19 or depending on the desired resolution, a corresponding illumination setting is selected via a corresponding selection of the illuminated pupil facets 11. This is accomplished by a corresponding tilting of the tiltable field facets 7 and also of the switching pupil facets 11_{S}. This tilting is controlled by a central control device 37a, which is schematically illustrated in FIG. 1.

Different boundary conditions can be used to specify the proportion A of a number of switching pupil facets 11_{S} in a total number N_{ges} of the pupil facets 11 of the pupil facet mirror 10. A desired pupil filling degree p of the illumination optical unit 25 can be specified. The pupil filling degree p is defined as a proportion of a pupil surface of the illumination optical unit 25 to which illumination light is applied with respect to the entire pupil surface.

For further details, reference should be made to DE 10 2018 214 223 A1.

After selecting an illumination setting, a section of the reticle 19 is then first projected onto the wafer 24 with the aid of the projection exposure apparatus 1. Afterwards, the light-sensitive layer on the wafer 24 that has been exposed with the illumination light 3 is developed.

What is claimed is:

1. An individual mirror of a pupil facet mirror, comprising:
a reflection surface having a surface normal;
a bearing configured to enable a pivoting movement of the individual mirror about first and second pivot axes, the first and second pivot axes being transverse to the surface normal; and
an actuator device configured to pivot the individual mirror, wherein a ratio of the pivotability of the individual mirror about the first and second pivot axes is at least 2:1.

2. The individual mirror of claim 1, wherein the first pivot axis has a first pivotability region, the second pivot axis has a second pivotability region, and smaller of the first and second pivotability regions is at most +/−25 mrad.

3. The individual mirror of claim 1, wherein a bearing for each pivoting degree of freedom comprises one or more leaf springs, and the one or more leaf springs for one pivoting degree of freedom are thicker and/or stiffer than the one or more leaf springs for the other pivoting degree of freedom.

4. The individual mirror of claim 1, further comprising a sensor device configure to detect at most one of the pivoting movements about the first and second pivot axes.

5. The individual mirror of claim 1, further comprising an eddy current sensor configured to detect a pivot position.

6. The individual mirror of claim 1, wherein the first and second pivot axes are spaced apart from the reflection surface.

7. The individual mirror of claim 1, further comprising a reference position sensor configured to ascertain a reference signal for a pivot position for at least one of the first and second pivot axes.

8. The individual mirror of claim 1, wherein the ratio of the pivotability about the first and second pivot axes differs from a ratio of the extents of the reflection surface of the individual mirror in the respective directions.

9. The individual mirror of claim 1, wherein the reflection surface has identical dimensions in the direction perpendicular to the two pivot axes.

10. The individual mirror of claim 1, wherein:
the first pivot axis has a first pivotability region, the second pivot axis has a second pivotability region, and smaller of the first and second pivotability regions is at most +/−25 mrad; and
a bearing for each pivoting degree of freedom comprises one or more leaf springs, and the one or more leaf springs for one pivoting degree of freedom are thicker and/or stiffer than the one or more leaf springs for the other pivoting degree of freedom.

11. The individual mirror of claim 10, further comprising a sensor device configure to detect at most one of the pivoting movements about the first and second pivot axes.

12. A pupil facet mirror, comprising:
a plurality of individual mirrors,
wherein each individual mirror is an individual mirror according to claim 1.

13. An optical unit, comprising:
a field facet mirror comprising a plurality of field facets; and
a pupil facet mirror comprising a plurality of individual mirrors,
wherein the optical unit is an illumination optical unit, the field facets are imageable into an object field, and each individual mirror of the pupil facet is an individual mirror according to claim 1.

14. The optical unit of claim 13, wherein at least some of the pupil facets are displaceable so that they are assignable to exactly two, three, four or five different field facets.

15. The optical unit of claim 13, wherein the individual mirrors of the pupil facet mirror are aligned so that they have a smaller pivotability region in a cross-scanning direction than in a scanning direction.

16. An apparatus, comprising:
an illumination optical unit, comprising:
a field facet mirror comprising a plurality of field facets; and
a pupil facet mirror comprising a plurality of individual mirrors;
a radiation source configured to generate illumination radiation; and
a projection optical unit,
wherein:
the field facets are imageable into an object field of the projection optical unit;
each individual mirror of the pupil facet is an individual mirror according to claim 1; and
the projection optical unit is configured to image the object field into an image field of the projection optical unit; and
the apparatus is a microlithographic projection exposure apparatus.

17. A method of using a microlithographic projection exposure apparatus comprising an illumination optical unit and a projection optical unit, the method comprising:
using the illumination optical unit to illuminate at least a portion of an object field; and
using the projection optical unit to image the illuminated portion of the object field into an image field,
wherein:
the illumination optical unit comprises:
a field facet mirror comprising a plurality of field facets; and
a pupil facet mirror comprising a plurality of individual mirrors; and
each individual mirror of the pupil facet is an individual mirror according to claim 1.

18. A method, comprising:
providing a pupil facet mirror comprising a plurality of individual mirrors, each individual mirror of the pupil facet is an individual mirror according to claim 1;
pivoting an individual mirror at a constant pivoting speed;
ascertaining a profile of a counter-electromotive force;
ascertaining a jump site in the profile of the counter-electromotive force; and
ascertaining a calibration support point via a current value at the jump site.

19. The method of claim 18, comprising ascertaining two calibration support points for each pivoting degree of freedom, and using this information to ascertain offset and/or gain corrections.

20. The method of claim 18, comprising using a reference position sensor to ascertain a reference signal.
